(19) United States
(12) Patent Application Publication
(10) Pub. No.: US 2025/0306626 A1
(43) Pub. Date: Oct. 2, 2025

(54) SOURCE SYNCHRONOUS INTERFACE CIRCUIT AND DATA TRANSMISSION METHOD

(71) Applicant: Smarter Silicon (Shanghai) Technologies Co., Ltd., Shanghai (CN)

(72) Inventors: Zhiwen SUN, Shanghai (CN); Yao ZHAO, Shanghai (CN)

(21) Appl. No.: 19/078,917

(22) Filed: Mar. 13, 2025

(30) Foreign Application Priority Data
Mar. 29, 2024 (CN) 202410384787.X

(51) Int. Cl. G06F 1/12

(52) U.S. Cl. CPC G06F 1/12

(57) ABSTRACT

A source synchronous interface circuit includes a first circuit, a level conversion circuit, and a second circuit. The first circuit is located on a master voltage domain side and configured to: obtain valid data and convert a source clock signal into a source synchronous clock signal corresponding to the valid data. The level conversion circuit is configured to: perform level conversion on the valid data and the source synchronous clock signal outputted by the first circuit to a slave voltage domain range of the second circuit and output the valid data and the source synchronous clock signal after level conversion to the second circuit. The second circuit is located on a slave voltage domain side and configured to: receive the valid data and the source synchronous clock signal and store the valid data into an asynchronous data storage queue based on the source synchronous clock signal.

### CROSS-REFERENCES TO RELATED APPLICATIONS

The present disclosure claims priority to Chinese Patent Application No. 202410384787.X, filed on Mar. 29, 2024, the content of which is incorporated herein by reference in its entirety.

### TECHNICAL FIELD

The present disclosure relates to the field of data transmission, and more specifically, relates to a source synchronous interface circuit and a data transmission method.

### BACKGROUND

In chips supporting dynamic voltage and frequency scaling (DVFS) technology, processor modules typically operate within dynamically adjustable voltage domains, while external buses remain in relatively fixed voltage domains. To achieve data transfer across voltage domains, asynchronous bridge schemes are commonly used. These schemes employ asynchronous first-in-first-out (FIFO) queues to facilitate data transmission between different voltage domains. However, the asynchronous FIFO queues in cross-voltage-domain interfaces include all data and pointers, leading to an increased number of signals across voltage domains, which reduces the efficiency of data transmission.

### SUMMARY

One aspect of the present disclosure provides a source synchronous interface circuit, including a first circuit, a level conversion circuit, and a second circuit. The first circuit is located on a master voltage domain side and configured to: obtain, in response to a transmission request, valid data, and convert a source clock signal into a source synchronous clock signal corresponding to the valid data. The level conversion circuit is configured to: perform level conversion on the valid data and the source synchronous clock signal outputted by the first circuit to a slave voltage domain range of the second circuit and output the valid data and the source synchronous clock signal after level conversion to the second circuit. The second circuit is located on a slave voltage domain side and configured to: receive the valid data and the source synchronous clock signal after level conversion and store the valid data into an asynchronous data storage queue based on the source synchronous clock signal.

Another aspect of the present disclosure provides a data transmission method. The data transmission method includes: obtaining a transmission request; obtaining, based on the transmission request, valid data and converting a source clock signal into a source synchronous clock signal corresponding to the valid data; performing level conversion on the valid data and the source synchronous clock signal from a master voltage domain range to a slave voltage domain range; and storing the valid data into an asynchronous data storage queue within the slave voltage domain range based on the source synchronous clock signal.

Another aspect of the present disclosure provides a system. The system includes one or more processors and a memory containing computer instructions that, when being executed, cause the one or more processors to execute a data transmission method that comprises: obtaining valid data and a source synchronous clock signal transmitted by a first circuit on a master voltage domain side after level conversion; storing the valid data into an asynchronous data storage queue within the second circuit based on the source synchronous clock signal; generating a ready clock signal when the asynchronous data storage queue has data output; and converting the ready clock signal into a source synchronous handshake signal, performing level conversion, and outputting the source synchronous handshake signal after level conversion to the first circuit, so that the first circuit is able to transmit data to a slave voltage domain side based on the source synchronous handshake signal.

### BRIEF DESCRIPTION OF THE DRAWINGS

In order to further illustrate the technical solutions in the embodiments of the present disclosure, a brief introduction is provided below for the drawings required for the description of the embodiments or related technologies. Apparently, the drawings in the following description are merely some embodiments of the present disclosure. Those skilled in the art may also obtain other drawings based on the provided drawings without exerting creative efforts.

FIG. 1 illustrates a structural schematic diagram of a source synchronous interface circuit according to some embodiments of the present disclosure.

FIG. 2 illustrates a structural schematic diagram of a first circuit according to some embodiments of the present disclosure.

FIG. 3 illustrates a structural schematic diagram of a second circuit according to some embodiments of the present disclosure.

FIG. 4 illustrates a schematic diagram of a source synchronous interface circuit according to some embodiments of the present disclosure.

FIG. 5 illustrates a schematic diagram of a timing correspondence of different clock signals according to some embodiments of the present disclosure.

FIG. 6 illustrates a circuit diagram of a source synchronous interface circuit according to some embodiments of the present disclosure.

FIG. 7 illustrates a schematic diagram of a timing path convergence on both sides of a source synchronous interface circuit according to some embodiments of the present disclosure.

FIG. 8 illustrates a flowchart of a data transmission method according to some embodiments of the present disclosure.

### DETAILED DESCRIPTION

The technical solutions in the embodiments of the present disclosure will be described below with reference to the accompanying drawings in the embodiments of the present disclosure. Obviously, the described embodiments are only some embodiments of the present disclosure, rather than all of the embodiments. Based on the embodiments of the present disclosure, all other embodiments obtained by those skilled in the art without creative efforts fall within the scope of protection of the present disclosure.

The present disclosure provides a source synchronous interface circuit. FIG. 1 illustrates a structural schematic diagram according to some embodiments of the present disclosure. The source synchronous interface circuit includes a first circuit 11, a level conversion circuit 12, and a second circuit 13.

The first circuit 11 is located on a master voltage domain side and is configured to respond to a transmission request, obtain valid data, and convert a source clock signal into a source synchronous clock signal corresponding to the valid data.

The level conversion circuit 12 is configured to perform level conversion on the valid data and the source synchronous clock signal outputted by the first circuit 11 to a slave voltage domain range of the second circuit 13, and to output the valid data and the source synchronous clock signal after level conversion to the second circuit 13.

The second circuit 13 is located on a slave voltage domain side and is configured to receive the valid data and the source synchronous clock signal after level conversion and store the valid data into an asynchronous data storage queue based on the source synchronous clock signal.

In chips supporting dynamic voltage and frequency scaling (DVFS) technology, processor(s) operate in dynamically adjustable voltage domains, while external buses remain in relatively fixed voltage domains. To achieve data transfer across voltage domains, asynchronous bridge schemes are commonly used. These schemes use asynchronous first-in-first-out (FIFO) queues to facilitate data transmission between different voltage domains. In cross-voltage-domain interfaces, all data and pointers in the asynchronous FIFO queues must cross voltage domains, resulting in a large number of cross-voltage-domain signals, which decreases the efficiency of data transmission. For example, a typical AX14 asynchronous bridge may require approximately 2500 cross-voltage-domain signals, where each signal requires a level conversion. This increases the area and power consumption.

Based on this, the present solution places an asynchronous data storage queue in a right part of the source synchronous interface circuit, i.e., on the slave voltage domain side. The source synchronous interface circuit effectively functions as an asynchronous bridge, where the asynchronous data storage queue is located on the right side of the asynchronous bridge. This arrangement requires only the valid data and the source synchronous clock signal transmitted from the master voltage domain side to the slave voltage domain side to cross the voltage domain. The data such as pointers in the asynchronous data storage queue are not required to cross the voltage domain, thereby reducing the amount of data crossing the voltage domain and improving data processing efficiency. Additionally, adopting this solution significantly reduces the amount of data crossing the voltage domain. For instance, in a typical AX14 asynchronous bridge, the number of cross-voltage-domain signals may be reduced to approximately 470 signals, compared to 2500 signals. This significant reduction also decreases the number of level conversions required, addressing the issues of increased area and power consumption caused by excessive level conversions, while also reducing the complexity of back-end routing.

Specifically, the source synchronous interface circuit as disclosed may include: a first circuit 11 located on the master voltage domain side, a second circuit 13 located on the slave voltage domain side, and a level conversion circuit 12 located between the first circuit 11 and the second circuit 13. The asynchronous bridge functionality is achieved through the first circuit 11, the level conversion circuit 12, and the second circuit 13 within the source synchronous interface circuit.

The first circuit 11 is located on the master voltage domain side. When there is a transmission request, the first circuit 11 transmits data to the second circuit 13, located on the slave voltage domain side, through the level conversion circuit 12.

When the first circuit 11 transmits data to the second circuit 13 based on the transmission request, the first circuit 11 first obtains valid data, i.e., data payload to be transmitted to the second circuit 13. The valid data payload has corresponding timing. The valid data is obtained through a bus on the master voltage domain side, and the timing of the valid data is determined at the bus on the master voltage domain side.

To ensure that the valid data payload is collected after being transmitted to the slave voltage domain side, the source clock signal is converted into a source synchronous clock signal corresponding to the valid data. Specifically, the source clock signal is adjusted based on the timing of the valid data to generate a source synchronous clock signal corresponding to the timing of the valid data. Only when data is collected using the source synchronous clock signal corresponding to the valid data, the valid data may be successfully collected. Therefore, the source synchronous clock signal corresponding to the valid data and the valid data itself are transmitted to the second circuit, allowing the second circuit to perform data collection. The source clock signal matches a master clock (mclk) signal of the bus on the master voltage domain side.

After the first circuit 11 converts the source clock signal into the source synchronous clock signal corresponding to the valid data, the first circuit 11 outputs the source synchronous clock signal and the valid data to the level conversion circuit 12. This enables the level conversion circuit 12 to perform level conversion on received data, adapting the received data to the slave voltage domain. Specifically, the source synchronous clock signal and the valid data are level-converted to the slave voltage domain range of the second circuit 13, thereby achieving cross-voltage-domain transmission of the valid data and the source synchronous clock signal.

After the second circuit 13 receives the valid data and the source synchronous clock signal that have undergone level conversion, the second circuit 13 stores the valid data into an asynchronous data storage queue included in the second circuit 13. In this process, the valid data first requires to be collected. Based on the source synchronous clock signal corresponding to the clock of the valid data, the valid data is collected and stored in the asynchronous data storage queue, thereby completing the cross-voltage-domain transmission of the valid data and the source synchronous clock signal, as well as the data storage after crossing the voltage domain.

It should be noted that any signal or data transmission between the first circuit 11 and the second circuit 13 requires to pass through the level conversion performed by the level conversion circuit 12. This ensures that the transmitted signals or data are adapted to the voltage domain range of the receiving end. For example, data transmitted from the first circuit 11 to the second circuit 13 is adapted to the slave voltage domain range of the second circuit 13 after undergoing level conversion by the level conversion circuit 12; and data transmitted from the second circuit 13 to the first circuit 11 is adapted to the master voltage domain range of the first circuit 11 after undergoing level conversion by the level conversion circuit 12.

As disclosed herein, the source synchronous interface circuit requires only the valid data and the source synchronous clock signal to cross the voltage domain, thereby reducing the amount of cross-voltage-domain data. This improves data processing efficiency and reduces issues such as increased area and power consumption caused by an excessive number of level conversions due to a large amount of cross-voltage-domain data. Additionally, it also reduces the complexity of back-end routing. Furthermore, by placing the asynchronous data storage queue on the slave voltage domain side and converting the clock signal and the data from the master voltage domain side to the slave voltage domain side, the working frequency of the bus is maintained without being reduced due to the impact of timing convergence, even when the circuits in the two voltage domains are separated by a considerable distance.

As disclosed, a source synchronous interface circuit includes a first circuit located on a master voltage domain side, a level conversion circuit, and a second circuit located on a slave voltage domain side. The first circuit responds to a transmission request by obtaining valid data and converting a source clock signal into a source synchronous clock signal corresponding to the valid data. The level conversion circuit performs level conversion on the valid data and the source synchronous clock signal, to adapt the valid data and the source synchronous clock signal to the slave voltage domain range of the second circuit. The second circuit receives the valid data and the source synchronous clock signal after level conversion and stores the valid data into an asynchronous data storage queue based on the source synchronous clock signal. In this solution, the asynchronous data storage queue is placed on the slave voltage domain side. The valid data and the source synchronous clock signal are transmitted from the master voltage domain side to the slave voltage domain side and stored in the asynchronous data storage queue on the slave voltage domain side. Thus, only the valid data and the source synchronous clock signal are required to cross the voltage domain, while other data in the asynchronous data storage queue is not required to cross the voltage domain. This reduces the amount of data crossing the voltage domain and improves data processing efficiency.

Some embodiments of the present disclosure provide a source synchronous interface circuit. FIG. 1 illustrates a structural schematic diagram of the source synchronous interface circuit. The source synchronous interface circuit includes a first circuit 11, a level conversion circuit 12, and a second circuit 13.

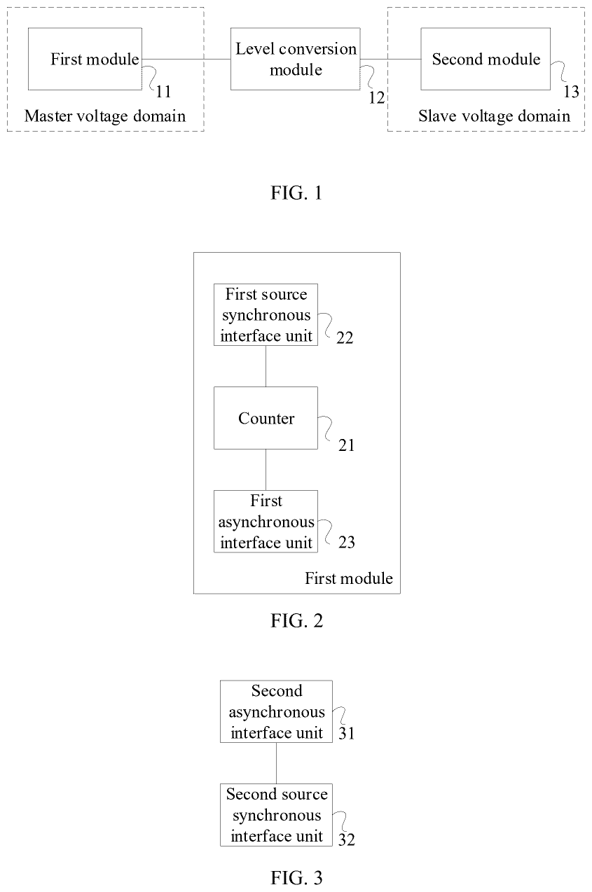

In addition to the structure in accordance with the previous embodiment, the first circuit 11, as shown in FIG. 2 according to some embodiments of the present disclosure, may include a counter 21 and a first source synchronous interface unit 22.

The counter 21 is configured to record a number of idle positions in an asynchronous data storage queue of the second circuit 13 and output a count value.

The first source synchronous interface unit 22 is configured to: determine whether the count value meets a condition; and convert, when the count value meets the condition, a source clock signal into a source synchronous clock signal corresponding to the valid data and output the source synchronous clock signal to the level conversion circuit 12.

The first circuit 11 outputs the valid data obtained after level conversion to the second circuit 13 and stores the valid data in the asynchronous data storage queue included in the second circuit 13. The depth of the asynchronous data storage queue is limited. To ensure that every time the first circuit 11 transmits data to the second circuit 13, there is an idle position in the asynchronous data storage queue for storage, the counter 21 is set in the first circuit 11 to record the number of idle positions in the asynchronous data storage queue of the second circuit 13.

When data is required to be transmitted from the first circuit 11 to the second circuit 13 and stored in the asynchronous data storage queue of the second circuit 13, the count value of the counter 21 first is required to be read. The counter records the number of idle positions in the asynchronous data storage queue of the second circuit 13, and the number serves as the count value. As long as the count value on the counter is determined to be non-zero, it may be confirmed that the count value meets the condition. When the count value meets the condition, data may be transmitted to the second circuit 13.

The count value is non-zero, indicating there is an idle position in the asynchronous data storage queue of the second circuit 13, and the data transmitted from the first circuit 11 may be received and stored. Therefore, once the count value is determined to be non-zero, the source clock signal is converted into a source synchronous clock signal corresponding to the valid data. So that after obtaining the source synchronous clock signal, the first source synchronous interface unit 22 may transmit the source synchronous clock signal after level conversion to the second circuit 13. The second circuit 13 may then store the valid data transmitted by the first circuit 11 into the idle position of the asynchronous data storage queue based on the source synchronous clock signal, thereby achieving cross-voltage-domain data transmission.

The conversion of the source clock signal into the source synchronous clock signal corresponding to the valid data may be achieved by setting a phase-locked loop (PLL) or a delay circuit in the first source synchronous interface unit 22 to adjust the timing of the source clock signal so that it corresponds to the timing of the valid data. Alternatively, a clock delay or a pulse width may be adjusted by adjusting a length of a clock signal line, so that the source synchronous clock signal obtained after conversion from the source clock signal matches the valid data.

The first source synchronous interface unit 22 in the first circuit 11 is not required to wait for a handshake signal from the second circuit 13 indicating that the second circuit 13 may receive data transmitted by the first circuit 11. As long as the count value meets the condition, it may be confirmed that the asynchronous data storage queue of the second circuit 13 is capable of receiving data. At this point, the data to be transmitted may be directly sent to the second circuit 13, improving transmission efficiency.

Additionally, in this solution, the count value is reduced when the first source synchronous interface unit 22 outputs the source synchronous clock signal.

When the first source synchronous interface unit 22 in the first circuit 11 outputs the source synchronous clock signal to the level conversion circuit 12, it indicates that the asynchronous data storage queue in the second circuit 13 is about to receive data transmitted by the first circuit 11. Consequently, the number of idle positions in the asynchronous data storage queue decreases. Therefore, in this solution, as soon as the first source synchronous interface unit 22 outputs the source synchronous clock signal, the count value of the counter 21 is directly reduced. This ensures that the count value of the counter 21 remains consistent with the number of idle positions in the asynchronous data storage queue, preventing a scenario where data has already been transmitted from the first circuit 11 and stored in the asynchronous data storage queue of the second circuit 13, but the count value of the counter 21 has not been reduced. Such a scenario leads to the first source synchronous interface unit 22 continuing to transmit data to the level conversion circuit 12 based on the count value, even though there are no idle positions available in the asynchronous data storage queue of the second circuit 13 to receive the transmitted data.

Furthermore, the count value of the counter 21 may also be updated based on a handshake signal transmitted by the second circuit 13.

When data is outputted from the asynchronous data storage queue in the second circuit 13, the number of idle positions in the asynchronous data storage queue increases. At this point, a handshake signal may be transmitted to the first circuit 11 so that the counter 21 in the first circuit 11 increases the count value based on the handshake signal. This ensures that the count value remains consistent with the number of idle positions in the asynchronous data storage queue at all times.

The source synchronous interface circuit as disclosed herein sets the asynchronous data storage queue on the slave voltage domain side. The valid data and the source synchronous clock signal are transmitted from the master voltage domain side to the slave voltage domain side and stored in the asynchronous data storage queue on the slave voltage domain side. Thus, only the valid data and the source synchronous clock signal are required to cross the voltage domain, while other data in the asynchronous data storage queue is not required to cross the voltage domain. This reduces the amount of data crossing the voltage domain and improves data processing efficiency. To ensure that there are idle positions in the asynchronous data storage queue when transmitting the valid data and the source synchronous clock signal to the slave voltage domain side, the counter is set in the first circuit to record the number of idle positions in the asynchronous data storage queue. Data is transmitted to the level conversion circuit only when the count value recorded by the counter meets the condition. After level conversion, the data is stored in the asynchronous data storage queue in the second circuit. This ensures that the first circuit determine whether to output the relevant data to the level conversion circuit based on the count value of idle positions in the asynchronous data storage queue of the second circuit, guaranteeing that the data obtained by the first circuit may be promptly transmitted to the second circuit.

Furthermore, as shown in FIG. 2, the first circuit 11 in the source synchronous interface circuit as disclosed may also include a first asynchronous interface unit 23.

The first asynchronous interface unit 23 is configured to obtain a source synchronous handshake signal outputted by the second circuit 13 via the level conversion circuit 12 and generate a bus synchronous handshake signal of the first circuit 11 based on the source synchronous handshake signal. The bus synchronous handshake signal is then outputted to the bus on the master voltage domain side so that the bus on the master voltage domain side may transmit data to the slave voltage domain side based on the bus synchronous handshake signal. Additionally, the counter 21 may update the count value based on the bus synchronous handshake signal.

The source synchronous handshake signal is configured to indicate that there is data output in the asynchronous data storage queue, allowing the counter 21 in the first circuit 11 to increase the count value based on the source synchronous handshake signal.

When data is outputted from the asynchronous data storage queue in the second circuit 13, the number of idle positions in the asynchronous data storage queue increases. At this time, a source synchronous handshake signal may be generated and transmitted to the first asynchronous interface unit 23 in the first circuit 11 via the level conversion circuit 12. The level conversion circuit 12 performs level conversion on the source synchronous handshake signal from the second circuit 13 to adapt the source synchronous handshake signal to the master voltage domain range before transmitting it to the first asynchronous interface unit 23.

After receiving the source synchronous handshake signal, the first asynchronous interface unit 23 generates a bus synchronous handshake signal and transmits the bus synchronous handshake signal to the bus on the master voltage domain side. Upon receiving the bus synchronous handshake signal, the bus on the master voltage domain side determines that the bus may continue transmitting data to the second circuit 13. Consequently, the bus on the master voltage domain side transmits the valid data received to the level conversion circuit 12, and then the level conversion circuit 12 performs level conversion and outputs the data to the second circuit 13.

Additionally, when the bus on the master voltage domain side receives the bus synchronous handshake signal, it is determined that data has been outputted from the asynchronous data storage queue in the second circuit 13 by the bus on the slave voltage domain side. This indicates that the number of idle positions in the asynchronous data storage queue increases. The count value of the counter 21 in the first circuit 11 may be incremented to ensure that the count value of the counter 21 on the master voltage domain side remains consistent with the number of idle positions in the asynchronous data storage queue on the slave voltage domain side, guaranteeing the effective transmission of data.

As disclosed, FIG. 1 illustrates the structural schematic diagram of the source synchronous interface circuit. The source synchronous interface circuit includes a first circuit 11, a level conversion circuit 12, and a second circuit 13.

In addition to the structure of the previous embodiment, as shown in FIG. 3, the second circuit in some embodiments may also include a second asynchronous interface unit 31 and a second source synchronous interface unit 32.

The second asynchronous interface unit 31 includes an asynchronous data storage queue. The asynchronous data storage queue is configured to: store valid data based on the source synchronous clock signal, and output data from the asynchronous data storage queue to the bus on the slave voltage domain side.

The second source synchronous interface unit 32 is configured to: receive a ready clock signal outputted by the bus on the slave voltage domain side, convert the ready clock signal into a source synchronous handshake signal, and transmit the source synchronous handshake signal to the level conversion circuit 12.

The asynchronous data storage queue is located within the second asynchronous interface unit 31 in the second circuit 13. The valid data and the source synchronous clock signal from the first circuit 11, after level conversion by the level conversion circuit 12, are transmitted to the second asynchronous interface unit 31 in the second circuit 13. In the second asynchronous interface unit 31, the valid data is stored into the asynchronous data storage queue based on the source synchronous clock signal, completing the cross-voltage-domain transmission of the valid data and the source synchronous clock signal.

The data stored in the asynchronous data storage queue may be outputted via the bus on the slave voltage domain side. When data is outputted from the asynchronous data storage queue via the bus on the slave voltage domain side, the bus on the slave voltage domain side generates a ready clock signal. The ready clock signal serves as feedback indicating that data from the asynchronous data storage queue has been received and outputted. The ready clock signal is transmitted from the bus on the slave voltage domain side to the second source synchronous interface unit 32, and the second source synchronous interface unit 32 converts the received ready clock signal into a source synchronous handshake signal. The source synchronous handshake signal indicates that data has been outputted from the asynchronous data storage queue and also signifies that the second circuit 13 on the slave voltage domain side is ready to receive additional data. The second source synchronous interface unit 32 transmits the source synchronous handshake signal to the level conversion circuit 12. The level conversion circuit 12 performs level conversion on the source synchronous handshake signal to the master voltage domain range and transmits the source synchronous handshake signal after level conversion to the first circuit 11, where the first asynchronous interface unit in the first circuit 11 receives the source synchronous handshake signal.

After receiving the source synchronous handshake signal, the first asynchronous interface unit generates a bus synchronous handshake signal for the first circuit 11 based on the source synchronous handshake signal, and outputs the bus synchronous handshake signal to the bus on the master voltage domain side. The bus on the master voltage domain side transmits the obtained data to the slave voltage domain side based on the bus synchronous handshake signal. Specifically, when the first circuit 11 transmits valid data and the source synchronous clock signal to the level conversion circuit 12, the first circuit 11 does not transmit the valid data and the source synchronous clock signal together. Instead, the valid data and the source synchronous clock signal are transmitted separately. The bus on the master voltage domain side directly transmits the valid data to the level conversion circuit 12. While, after the first source synchronous interface unit receives the source clock signal outputted by the bus on the master voltage domain side, the first source synchronous interface unit converts the source clock signal into a source synchronous clock signal corresponding to the valid data, and transmits source synchronous clock signal after conversion to the level conversion circuit 12.

Furthermore, the level conversion circuit 12, configured for data transmission between the first circuit 11 and the second circuit 13, may include a first level conversion unit and a second level conversion unit.

The first level conversion unit is configured to: perform level conversion on the valid data and the source synchronous clock signal outputted by the first circuit 11, to adapt the valid data and the source synchronous clock signal to the slave voltage domain range; and output the valid data and the source synchronous clock signal after conversion to the second circuit 13. The second level conversion unit is configured to: perform level conversion on the source synchronous handshake signal of the second circuit 13, to adapt the source synchronous handshake signal to the master voltage domain range; and output the source synchronous handshake signal after conversion to the first circuit 11.

Thus, the first level conversion unit and the second level conversion unit are respectively configured to convert data, which is required to be transmitted, into an appropriate voltage domain range.

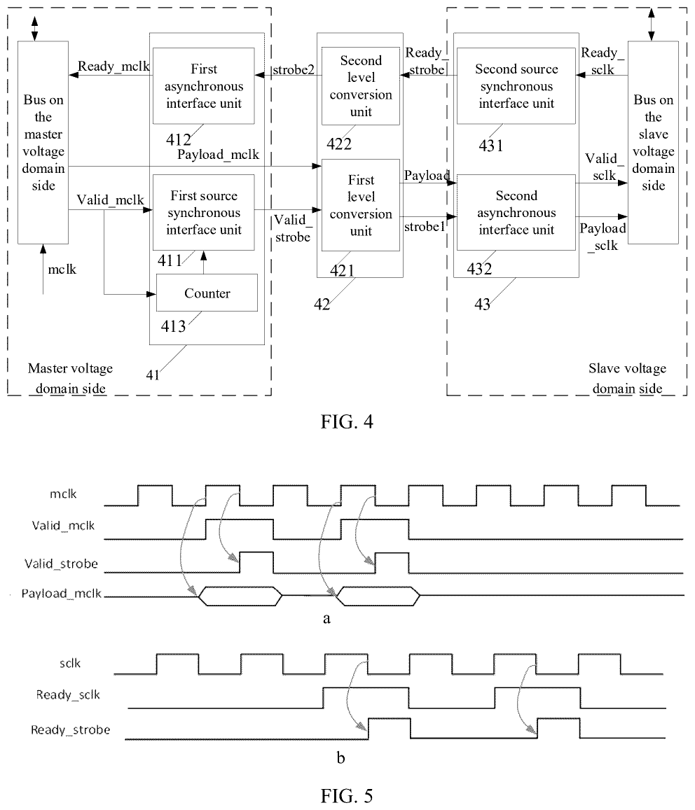

Specifically, as shown in FIG. 4, the source synchronous interface circuit as disclosed may include: a first circuit 41, a level conversion circuit 42, and a second circuit 43. The first circuit 41 may include a first source synchronous interface unit 411, a first asynchronous interface unit 412, and a counter 413. The second circuit 43 may include a second source synchronous interface unit 431 and a second asynchronous interface unit 432. The level conversion circuit 42 may include a first level conversion unit 421 and a second level conversion unit 422.

The first circuit 41 is located on a master voltage domain side (Master), and the second circuit 43 is located on a slave voltage domain side (Slave). The bus (BUS) on the master voltage domain side obtains valid data and transmits the valid data payload to the first level conversion unit 421 with a timing Payload_mclk of the bus. The first level conversion unit 421 performs level conversion on the valid data and transmits the valid data to the second asynchronous interface unit 432. The bus (BUS) on the master voltage domain side also obtains a source clock signal mclk generated by a clock generator. Under the source clock signal, the bus transmits a valid signal (Valid) to the first source synchronous interface unit 411, i.e., transmitting Valid_mclk. The first source synchronous interface unit 411 converts the valid signal Valid_mclk into a source synchronous clock signal Valid_strobe corresponding to the timing Payload_mclk of the valid data payload and transmits the source synchronous clock signal Valid_strobe to the first level conversion unit 421. The first level conversion unit 421 performs level conversion on the source synchronous clock signal and transmits the source synchronous clock signal to the second asynchronous interface unit 432.

The second asynchronous interface unit 432 obtains the valid data payload and the source synchronous clock signal Valid_strobe. Based on the source synchronous clock signal Valid_strobe, the valid data payload is stored into an asynchronous data storage queue (FIFO) within the second asynchronous interface unit 432, completing the cross-voltage-domain transmission of the valid data payload and the source synchronous clock signal Valid_strobe.

When the data stored in the asynchronous data storage queue (FIFO) in the second asynchronous interface unit 432 is outputted via the bus on the slave voltage domain side, the data in the asynchronous data storage queue (FIFO) is outputted with a timing, Payload_sclk. Based on the output of data from the asynchronous data storage queue (FIFO), the bus on the slave voltage domain side generates a ready clock signal Ready_sclk and sends the ready clock signal Ready_sclk to the second source synchronous interface unit 431. The second source synchronous interface unit 431 converts the ready clock signal Ready_sclk into a source synchronous handshake signal Ready_strobe and transmits the source synchronous handshake signal Ready_strobe to the second level conversion unit 422. The second level conversion unit 422 performs level conversion and transmits the source synchronous handshake signal to the first asynchronous interface unit 412. The first asynchronous interface unit 412 obtains the source synchronous handshake signal Ready_strobe after level conversion as the source synchronous handshake signal strobe2, and generates a bus synchronous handshake signal Ready_mclk based on the source synchronous handshake signal Ready_strobe. The first asynchronous interface unit 412 transmits the bus synchronous handshake signal Ready_mclk to the bus on the master voltage domain side, enabling the bus on the master voltage domain side to transmit the received valid data to the first level conversion unit 421 for a next data transmission.

Additionally, since the first circuit 41 transmits the valid data and the source synchronous clock signal to the level conversion circuit 42 separately, the first level conversion unit 421 may include a first level conversion sub-unit and a second level conversion sub-unit.

The first level conversion sub-unit is configured to: perform level conversion on the valid data outputted by the first circuit 41 to adapt the valid data to the slave voltage domain range; and output the valid data to the second circuit 43. The second level conversion sub-unit is configured to: perform level conversion on the source synchronous clock signal outputted by the first circuit 41 to adapt the source synchronous clock signal to the slave voltage domain range of the second circuit 43; and output the source synchronous clock signal to the second circuit 43. That is, for each type of data being transmitted, a corresponding level conversion sub-unit is provided to facilitate data transmission.

The units in the first circuit and the second circuit correspond to each other. Therefore, in the current scenario, the first circuit is located on the master voltage domain side, and the second circuit is located on the slave voltage domain side. In other scenarios, the first circuit may be located on the slave voltage domain side, and the second circuit may be located on the master voltage domain side. That is, the structures of the first circuit and the second circuit are consistent, and different configurations are used when located on the slave voltage domain side or the master voltage domain side to achieve different functions.

It should be noted that the first source synchronous interface unit 411 converts the source clock signal into a source synchronous clock signal corresponding to the valid data by determining a timing of the valid data and a timing difference between the valid data and the source synchronous clock signal that meets a condition. Based on the timing of the valid data and the timing difference that meets the condition, the source synchronous clock signal corresponding to the valid data is determined.

The source synchronous clock signal is required to correspond to the valid data to ensure that the valid data may be collected using the source synchronous clock signal. Therefore, when determining the source synchronous clock signal, it is necessary to first determine the timing of the valid data. Part a of FIG. 5 illustrates a timing relationship among the source clock mclk (e.g., system clock), the valid signal clock Valid_mclk, the source synchronous clock Valid_strobe, and the valid data clock Payload_mclk.

The valid signal clock Valid_mclk and the valid data clock Payload_mclk are aligned and are synchronously outputted by the bus on the master voltage domain side. Therefore, when the source synchronous clock Valid_strobe is generated, the source synchronous clock Valid_strobe is required to meet the timing requirements relative to the valid data clock Payload_mclk. As long as a rising edge of the source synchronous clock Valid_strobe located within the pulse of the valid data clock Payload_mclk, i.e., within a valid window of the valid data, which ensures that the valid data may be captured. Preferably, the rising edge of the source synchronous clock Valid_strobe is located in the middle of the valid window of the valid data to allow sufficient setup and hold times for the strobe signal pulse.

Thus, by determining the timing difference between the valid data and the source synchronous clock signal and combining with the timing corresponding to the valid data, the source synchronous clock signal corresponding to the valid data may be determined.

As shown in part b of FIG. 5, a timing diagram is provided for transmitting a handshake signal from the slave voltage domain to the master voltage domain. The timing diagram includes the source clock sclk from the slave voltage domain, the ready clock signal Ready_sclk, and the source synchronous handshake signal Ready_strobe.

The source synchronous handshake signal Ready_strobe is generated based on the ready clock signal Ready_sclk. In this case, as there is no data clock signal, the position of the rising edge of the source synchronous handshake signal Ready_strobe may be directly determined.

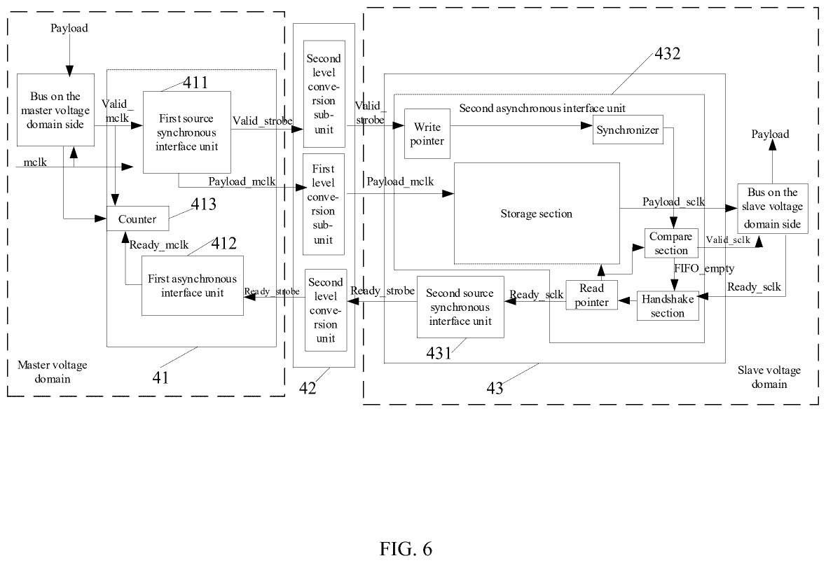

FIG. 6 illustrates a circuit diagram of a source synchronous interface circuit. The source synchronous interface circuit includes a first circuit 41, a level conversion circuit 42, and a second circuit 43. The first circuit 41 includes: a first source synchronous interface unit 411, a first asynchronous interface unit 412, and a counter 413. The second circuit 43 includes: a second source synchronous interface unit 431 and a second asynchronous interface unit 432. The level conversion circuit 42 includes: a first level conversion unit and a second level conversion unit. The first level conversion unit includes a first level conversion sub-unit and a second level conversion sub-unit.

The bus on the master voltage domain side (BUS) obtains valid data payload and transmits the valid data payload with a timing Payload_mclk of the valid data, to the first level conversion sub-unit. The first level conversion sub-unit performs level conversion and sends the valid data after conversion to the second asynchronous interface unit 432. The bus on the master voltage domain side (BUS) also obtains a source clock signal mclk generated by a clock generator. Under the source clock signal, the bus on the master voltage domain side sends a valid signal Valid to the first source synchronous interface unit 411 (i.e., sending Valid_mclk). The first source synchronous interface unit 411 converts the valid signal into a source synchronous clock signal Valid_strobe corresponding to the timing Payload_mclk of the valid data payload and sends the source synchronous clock signal Valid_strobe to the first level conversion unit. The first level conversion unit performs level conversion on the source synchronous clock signal and sends the source synchronous clock signal after conversion to the second asynchronous interface unit 432.

When the valid data payload is sent to the first level conversion sub-unit and the source synchronous clock signal Valid_strobe is sent to the first level conversion unit, the count value in the counter 413 changes.

The second asynchronous interface unit 432 receives the valid data payload and the source synchronous clock signal Valid_strobe. Before writing the valid data payload into a storage section of an asynchronous data storage queue FIFO in the second asynchronous interface unit 432 using the source synchronous clock signal Valid_strobe, the write pointer of the asynchronous data storage queue FIFO in the second asynchronous interface unit 432 first is required to be determined. The write pointer always points to a next address in the storage section of the FIFO where data is to be written. Based on this write pointer, a position in the storage section of the FIFO where the valid data payload is to be written is determined, completing the writing of the valid data payload. After the write operation is completed, the position pointed to by the write pointer changes.

When the data stored in the storage section of the asynchronous data storage queue FIFO in the second asynchronous interface unit 432 is outputted via the bus BUS on the slave voltage domain side, the data in the asynchronous data storage queue FIFO is outputted with a timing Payload_sclk. When the bus BUS on the slave voltage domain side reads data from the asynchronous data storage queue FIFO in the second asynchronous interface unit 432, the bus BUS first retrieves a read pointer. The read pointer indicates the address in the storage section of the asynchronous data storage queue FIFO where data may currently be read. The bus BUS on the slave voltage domain side reads data from the storage section of the asynchronous data storage queue FIFO based on the read pointer.

Additionally, the asynchronous data storage queue FIFO includes a compare section for comparing the read pointer and the write pointer obtained through a synchronizer to determine whether to generate a valid signal. If a valid signal is generated, the clock Valid_sclk of the valid signal is transmitted to the bus BUS on the slave voltage domain side. Based on the data outputted from the asynchronous data storage queue FIFO, the bus BUS on the slave voltage domain side generates a ready clock signal Ready_sclk and outputs the ready clock signal Ready_sclk to the second source synchronous interface unit 431. If the read pointer and the write pointer are the same, an empty signal FIFO_empty is generated and outputted to a handshake section to generate the ready clock signal Ready_sclk, and the ready clock signal Ready_sclk is then outputted to the second source synchronous interface unit 431.

The second source synchronous interface unit 431 converts the ready clock signal Ready_sclk into a source synchronous handshake signal Ready_strobe and transmits the source synchronous handshake signal Ready_strobe to the second level conversion unit. After level conversion by the second level conversion unit, the source synchronous handshake signal is transmitted to the first asynchronous interface unit 412. The first asynchronous interface unit 412 receives the source synchronous handshake signal Ready_strobe and generates a bus synchronous handshake signal Ready_mclk for the master voltage domain based on the source synchronous handshake signal Ready_strobe. The first asynchronous interface unit 412 transmits the bus synchronous handshake signal Ready_mclk to the counter 413 to update the count value in the counter 413. The counter 413 may then send the bus synchronous handshake signal Ready_mclk to the bus BUS on the master voltage domain side so that the bus BUS on the master voltage domain side may transmit the valid data received to the first level conversion unit for a next data transmission.

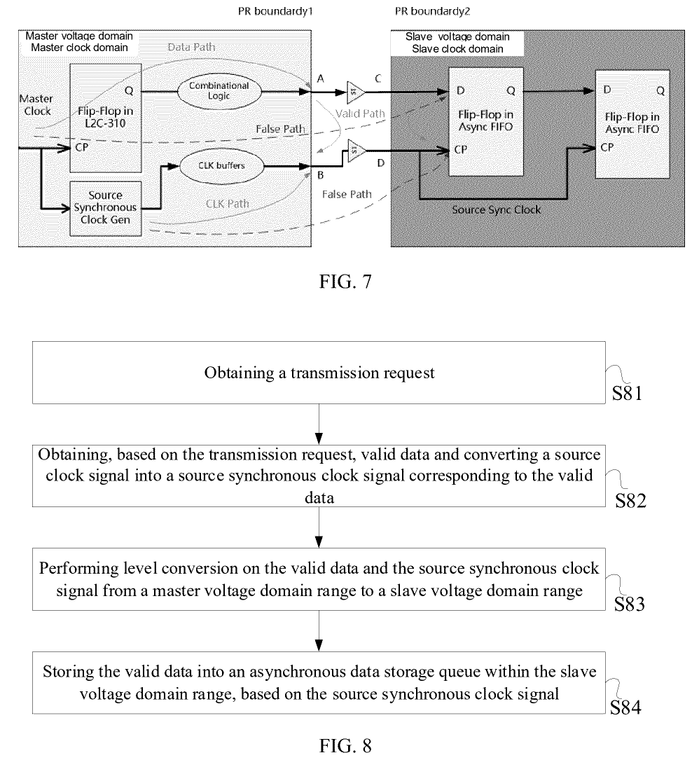

In the source synchronous interface circuit as disclosed, two sides of the level conversion circuit belong to different voltage domains, and the source synchronous clock signal and the source clock signal are considered different clock domains. FIG. 7 illustrates a schematic diagram of timing path convergence on two sides of the source synchronous interface circuit.

In FIG. 7, a transmission path of a master voltage domain is used as an example. Data Path represents a data path, where the data path has timing requirements and converges at the boundary PR boundary 1 on the master voltage domain side. Clk Path represents a clock path, where the clock path corresponds to the Data Path at the boundary PR boundaryl on the master voltage domain side, and both the data path and the clock path meet certain timing requirements. False Path represents an asynchronous path, where the asynchronous path does not have timing constraints and may traverse from the master voltage domain to the slave voltage domain without timing paths, only with signal constraints.

As shown by the solid arrows in the diagram (e.g., Data Path or Clk Path), there are no true timing paths between flip-flops in different voltage domains. All timing paths in the master voltage domain converge within the master voltage domain range, and all timing paths in the slave voltage domain converge within the slave voltage domain range. As shown by the dashed arrows in the diagram (e.g., False Path), no synchronization or clock convergence is required.

Additionally, in the source synchronous interface circuit as disclosed, during layout and routing, layout positions of two sides of the asynchronous bridge split by the source synchronous interface circuit are close to the corresponding voltage domain sides. For example, the position of the first circuit should be close to the master voltage domain side, and the position of the second circuit should be close to the slave voltage domain side. At the processor (module) code level, the code for the slave voltage domain part of the source synchronous interface circuit is at the same hierarchical level as the processor (module) and is not included within the processor module code.

The source synchronous interface circuit as disclosed places the asynchronous data storage queue on the slave voltage domain side. The valid data and the source synchronous clock signal are transmitted from the master voltage domain side to the slave voltage domain side and stored in the asynchronous data storage queue on the slave voltage domain side. Thus, only the valid data and the source synchronous clock signal cross the voltage domain, while other data in the asynchronous data storage queue is not required to cross the voltage domain. This reduces the amount of data crossing the voltage domain and improves data processing efficiency. To ensure that the valid data and the source synchronous clock signal are transmitted to the slave voltage domain side, when the asynchronous data storage queue on the slave voltage domain side has data output through the bus on the slave voltage domain side, a corresponding handshake signal is required to be transmitted to the first circuit. This allows the first circuit to promptly update the recorded number of idle positions in the asynchronous data storage queue, preventing a scenario where the asynchronous data storage queue still has idle positions, but the count value recorded by the counter indicates no idle positions, causing data to fail to be transmitted to the second circuit in a timely manner.

Some embodiments of the present disclosure provide a data transmission method, and FIG. 8 illustrates a flowchart of the data transmission method. The data transmission method includes:
Step S81: Obtaining a transmission request;
Step S82: Obtaining, based on the transmission request, valid data and converting a source clock signal into a source synchronous clock signal corresponding to the valid data;
Step S83: Performing level conversion on the valid data and the source synchronous clock signal from a master voltage domain range to a slave voltage domain range; and
Step S84: Storing the valid data into an asynchronous data storage queue within the slave voltage domain range, based on the source synchronous clock signal.

Further, converting the source clock signal into the source synchronous clock signal corresponding to the valid data includes: determining a number of idle positions in the asynchronous data storage queue and designating the number of idle positions as a count value; and converting, when the count value is determined to meet a condition, the source clock signal into the source synchronous clock signal corresponding to the valid data.

Additionally, converting the source clock signal into the source synchronous clock signal corresponding to the valid data includes: determining a timing of the valid data and a timing difference that meets a condition between the valid data and the source synchronous clock signal; and determining the source synchronous clock signal corresponding to the valid data, based on the timing of the valid data and the timing difference that meets the condition.

Further, the data transmission method as disclosed is applied to a first circuit located on a master voltage domain side, where the asynchronous data storage queue is located within a second circuit on a slave voltage domain side. A timing path in the first circuit converges within the master voltage domain range, and a timing path in the second circuit converges within the slave voltage domain range.

The data transmission method as disclosed is implemented based on the source synchronous interface circuit as disclosed above and will not be repeated here.

As disclosed, the data transmission method includes: obtaining a transmission request; obtaining, based on the transmission request, valid data and converting a source clock signal into a source synchronous clock signal corresponding to the valid data; performing level conversion on the valid data and the source synchronous clock signal from the master voltage domain range to the slave voltage domain range; and storing the valid data into an asynchronous data storage queue within the slave voltage domain range, based on the source synchronous clock signal. In this solution, the asynchronous data storage queue is set on the slave voltage domain side. The valid data and the source synchronous clock signal are transmitted from the master voltage domain side to the slave voltage domain side and stored in the asynchronous data storage queue on the slave voltage domain side. Thus, only the valid data and the source synchronous clock signal are required to cross the voltage domain, while other data in the asynchronous data storage queue is not required to cross the voltage domain. This reduces the amount of data crossing the voltage domain and improves data processing efficiency.

Further, some embodiments of the present disclosure provide another data transmission method. The data transmission method is applied to a second circuit located on a slave voltage domain side. The data transmission method includes:
Obtaining valid data and a source synchronous clock signal transmitted by the first circuit on a master voltage domain side after level conversion;
Storing the valid data into an asynchronous data storage queue based on the source synchronous clock signal;
Generating a ready clock signal when it is determined that the asynchronous data storage queue has data output; and
Converting the ready clock signal into a source synchronous handshake signal, performing level conversion, and outputting the source synchronous handshake signal after level conversion to the first circuit so that the first circuit may transmit data to the slave voltage domain side based on the source synchronous handshake signal.

The data transmission method as disclosed is implemented based on the source synchronous interface circuit as disclosed above and will not be repeated here.

In various embodiments, a system is provided including one or more processors and a memory containing computer instructions that, when being executed, cause the one or more processors to execute a data transmission method that comprises: obtaining valid data and a source synchronous clock signal transmitted by a first circuit on a master voltage domain side after level conversion; storing the valid data into an asynchronous data storage queue within the second circuit based on the source synchronous clock signal; generating a ready clock signal when the asynchronous data storage queue has data output; and converting the ready clock signal into a source synchronous handshake signal, performing level conversion, and outputting the source synchronous handshake signal after level conversion to the first circuit, so that the first circuit is able to transmit data to a slave voltage domain side based on the source synchronous handshake signal.

The data transmission method as disclosed places the asynchronous data storage queue on the slave voltage domain side. The valid data and the source synchronous clock signal are transmitted from the master voltage domain side to the slave voltage domain side and stored in the asynchronous data storage queue on the slave voltage domain side. Thus, only the valid data and source synchronous clock signal are required to cross the voltage domain, while other data in the asynchronous data storage queue is not required to cross the voltage domain. This reduces the amount of data crossing the voltage domain and improves data processing efficiency. To ensure that the valid data and the source synchronous clock signal are transmitted to the slave voltage domain side, when there is data output through the bus on the slave voltage domain side from the asynchronous data storage queue, a corresponding handshake signal is required to be transmitted to the first circuit. This allows the first circuit to promptly update the recorded number of idle positions in the asynchronous data storage queue based on the handshake signal, preventing a scenario where there are still idle positions in the asynchronous data storage queue, but the count value recorded by the counter indicates no idle positions, causing data to fail to be transmitted to the second circuit in a timely manner.

Various embodiments in this specification are described in a progressive manner, with each embodiment emphasizing differences from other embodiments. For similar or identical parts, reference is made to the other embodiments. For the devices disclosed in the embodiments, as they correspond to the methods disclosed in the embodiments, their descriptions are simplified, and reference may be made to the method descriptions where relevant.

Those skilled in the art will also recognize that the units and algorithm steps described in the examples of the embodiments disclosed herein may be implemented using electronic hardware, computer software, or a combination of both. To clarify the interchangeability of hardware and software, the components and steps of the examples have been generally described according to their functionality. Whether these functions are performed in hardware or software depends on the specific application and design constraints of the technical solution. Those skilled in the art may use different methods to implement the described functions for each specific application, but such implementations should not be considered beyond the scope of the present disclosure.

The methods or algorithm steps described in the embodiments disclosed herein may be implemented directly in hardware, software modules executed by one or more processor, or a combination of both. Software modules may be stored in random access memory (RAM), memory, read-only memory (ROM), electrically programmable ROM, electrically erasable programmable ROM, registers, hard disks, removable disks, CD-ROMs, or any other form of storage medium known in the art.

The above description of the disclosed embodiments enables those skilled in the art to implement or use the present disclosure. Various modifications to these embodiments will be apparent to those skilled in the art, and the general principles defined herein may be applied to other embodiments without departing from the spirit or scope of the present disclosure. Therefore, the present disclosure is not limited to the embodiments described herein but is to be accorded the broadest scope consistent with the principles and novel features disclosed herein.

What is claimed is:

1. A source synchronous interface circuit, comprising:
a first circuit, located on a master voltage domain side and configured to: obtain, in response to a transmission request, valid data, and convert a source clock signal into a source synchronous clock signal corresponding to the valid data;
a level conversion circuit, configured to: perform level conversion on the valid data and the source synchronous clock signal outputted by the first circuit to a slave voltage domain range of a second circuit, and output the valid data and the source synchronous clock signal after level conversion to the second circuit; and
the second circuit, located on a slave voltage domain side and configured to: receive the valid data and the source synchronous clock signal after level conversion, and store the valid data into an asynchronous data storage queue based on the source synchronous clock signal.

2. The source synchronous interface circuit according to claim 1, wherein the first circuit comprises:
a counter, configured to record a number of idle positions in the asynchronous data storage queue of the second circuit and output a count value; and
a first source synchronous interface unit, configured to:
determine whether the count value meets a condition; and
convert, when determining that the count value meets the condition, the source clock signal into the source synchronous clock signal corresponding to the valid data, and output the source synchronous clock signal to the level conversion circuit.

3. The source synchronous interface circuit according to claim 2, wherein the counter is configured to decrease the count value when the first source synchronous interface unit outputs the source synchronous clock signal.

4. The source synchronous interface circuit according to claim 1, wherein the first circuit converts the source clock signal into the source synchronous clock signal corresponding to the valid data by: determining a timing corresponding to the valid data and a timing difference that meets a condition between the valid data and the source synchronous clock signal, and determining the source synchronous clock signal corresponding to the valid data based on the timing corresponding to the valid data and the timing difference that meets the condition.

5. The source synchronous interface circuit according to claim 2, wherein the second circuit comprises:
a second asynchronous interface unit, comprising the asynchronous data storage queue, wherein the second asynchronous interface unit is capable of storing the valid data into the asynchronous data storage queue based on the source synchronous clock signal and outputting data from the asynchronous data storage queue to a bus on the slave voltage domain side; and
a second source synchronous interface unit, configured to receive a ready clock signal outputted by the bus on the slave voltage domain side and convert the ready clock signal into a source synchronous handshake signal for transmission to the level conversion circuit, wherein the source synchronous handshake signal is configured to indicate that the asynchronous data storage queue has data output, so that the counter in the first circuit increases the count value based on the source synchronous handshake signal.

6. The source synchronous interface circuit according to claim 5, wherein the first circuit further comprises: a first asynchronous interface unit, configured to:
obtain the source synchronous handshake signal outputted by the second source synchronous interface unit via the level conversion circuit;
generate a bus synchronous handshake signal of the first circuit based on the source synchronous handshake signal; and
output the bus synchronous handshake signal to a bus on the master voltage domain side, so that the bus on the master voltage domain side is able to transmit data to the slave voltage domain side based on the bus synchronous handshake signal,
wherein the counter is capable of updating the count value based on the bus synchronous handshake signal.

7. The source synchronous interface circuit according to claim 5, wherein the level conversion circuit at least comprises:
a first level conversion unit, configured to perform level conversion on the valid data and the source synchronous clock signal outputted by the first circuit to the slave voltage domain range of the second circuit and output the valid data and the source synchronous clock signal after level conversion to the second circuit; and
a second level conversion unit, configured to perform level conversion on the source synchronous handshake signal to a master voltage domain range of the first circuit and output the source synchronous handshake signal after level conversion to the first circuit.

8. The source synchronous interface circuit according to claim 7, wherein the first level conversion unit comprises:
a first level conversion sub-unit, configured to perform level conversion on the valid data outputted by the first circuit to the slave voltage domain range of the second circuit and output the valid data after level conversion to the second circuit; and
a second level conversion sub-unit, configured to perform level conversion on the source synchronous clock signal outputted by the first circuit to the slave voltage domain range of the second circuit and output the source synchronous clock signal after level conversion to the second circuit.

9. The source synchronous interface circuit according to claim 1, wherein a timing path in the first circuit converges within a master voltage domain range, and a timing path in the second circuit converges within the slave voltage domain range.

10. A data transmission method, comprising:
obtaining a transmission request;
obtaining, based on the transmission request, valid data and converting a source clock signal into a source synchronous clock signal corresponding to the valid data;
performing level conversion on the valid data and the source synchronous clock signal from a master voltage domain range to a slave voltage domain range; and
storing the valid data into an asynchronous data storage queue within the slave voltage domain range based on the source synchronous clock signal.

11. The method according to claim 10, wherein converting the source clock signal into the source synchronous clock signal comprises:
determining a number of idle positions in the asynchronous data storage queue and designating the number of idle positions as a count value; and
converting, when the count value is determined to meet a condition, the source clock signal into the source synchronous clock signal corresponding to the valid data.

12. The method according to claim 10, wherein converting the source clock signal into the source synchronous clock signal comprises:
determining a timing of the valid data and a timing difference that meets a condition between the valid data and the source synchronous clock signal; and
determining the source synchronous clock signal corresponding to the valid data, based on the timing of the valid data and the timing difference that meets the condition.

13. The method according to claim 10, wherein the data transmission method is applied to a first circuit located on a master voltage domain side, and the asynchronous data storage queue is located within a second circuit on a slave voltage domain side.

14. The method according to claim 13, wherein a timing path in the first circuit converges within the master voltage domain range, and a timing path in the second circuit converges within the slave voltage domain range.

15. A system, comprising:
one or more processors, and a memory containing computer instructions that, when being executed, cause the one or more processors to execute a data transmission method that comprises:
obtaining a transmission request;
obtaining, based on the transmission request, valid data and converting a source clock signal into a source synchronous clock signal corresponding to the valid data;
performing level conversion on the valid data and the source synchronous clock signal from a master voltage domain range to a slave voltage domain range; and
storing the valid data into an asynchronous data storage queue within the slave voltage domain range based on the source synchronous clock signal.

16. The system according to claim 15, wherein the one or more processors are further configured to perform:
determining a number of idle positions in the asynchronous data storage queue and designating the number of idle positions as a count value; and
converting, when the count value is determined to meet a condition, the source clock signal into the source synchronous clock signal corresponding to the valid data.

17. The system according to claim 15, wherein the one or more processors are further configured to perform:
determining a timing of the valid data and a timing difference that meets a condition between the valid data and the source synchronous clock signal; and
determining the source synchronous clock signal corresponding to the valid data, based on the timing of the valid data and the timing difference that meets the condition.

18. The system according to claim 15, wherein the data transmission method is applied to a first circuit located on a master voltage domain side, and the asynchronous data storage queue is located within a second circuit on a slave voltage domain side.

19. The system according to claim 18, wherein a timing path in the first circuit converges within the master voltage domain range, and a timing path in the second circuit converges within the slave voltage domain range.

20. The system according to claim 15, wherein the one or more processors are further configured to perform:
obtaining the valid data and the source synchronous clock signal transmitted by the first circuit on a master voltage domain side after level conversion;
storing the valid data into an asynchronous data storage queue within a second circuit based on the source synchronous clock signal;
generating a ready clock signal when the asynchronous data storage queue has data output; and
converting the ready clock signal into a source synchronous handshake signal, performing level conversion, and outputting the source synchronous handshake signal after level conversion to the first circuit, so that the first circuit is able to transmit data to a slave voltage domain side based on the source synchronous handshake signal.
